(19) United States
(12) Patent Application Publication
(10) Pub. No.: US 2014/0196775 A1
(43) Pub. Date: Jul. 17, 2014

(54) SYNTHESIS METHOD OF CU(IN,GA)SE2 NANOROD OR NANOWIRE AND MATERIALS INCLUDING THE SAME

(71) Applicant: KOREA INSTITUTE OF SCIENCE AND TECHNOLOGY, SEOUL (KR)

(72) Inventors: Ji Yeong LEE, Seoul (KR); Myoung Woon MOON, Seoul (KR); Won Kyung SEONG, Seoul (KR); Jong Ku PARK, Gyeonggi-do (KR); Cheol Woong YANG, Gyeonggi-do (KR); So Hye CHO, Seoul (KR); Kwang Ryeol LEE, Seoul (KR)

(73) Assignee: KOREA INSTITUTE OF SCIENCE AND TECHNOLOGY, SEOUL (KR)

(21) Appl. No.: 14/026,426

(22) Filed: Sep. 13, 2013

(30) Foreign Application Priority Data
Jan. 16, 2013 (KR) 10-2013-0005012

(51) Int. Cl. H01L 31/18; H01L 31/0352; H01L 31/0296

(52) U.S. Cl. CPC H01L 31/1828; H01L 31/0296; H01L 31/035227
USPC 136/255; 438/95; 257/431

(57) ABSTRACT

A method of fabricating CIGS nanorod or nanowire according to one exemplary embodiment of the present disclosure comprises a deposition preparation step of placing a raw material including copper, indium, gallium and selenium and a substrate, and a deposition step of growing CIGS nanorod or nanowire on the substrate by maintaining an internal temperature of a reactor, in which carrier gas flows at a constant flow rate, at a temperature in the range of 850 to 1000° C. According to the method, Cu(In,Ga)Se₂ nanorod or nanowire as a direct transition type semiconductor material having substantially uniform composition, high crystallinity and high light absorption ratio can be fabricated.

### CROSS-REFERENCE TO RELATED APPLICATION

Pursuant to 35 U.S.C. §119(a), this application claims the benefit of earlier filing date and right of priority to Korean Application No. 10-2013-0005012, filed on Jan. 16, 2013, the contents of which is incorporated by reference herein in its entirety.

### BACKGROUND OF THE DISCLOSURE

1. Field of the Disclosure

This specification relates to a synthesis method of Cu(In,Ga)Se₂ nanorod or nanowire, and materials including the Cu(In,Ga)Se₂ nanorod or nanowire, and more particularly, a method of providing nano-materials having substantially uniform composition and superior crystallinity using a thermal-chemical vapor deposition, and materials including the nanorods or nanowores.

2. Background of the Disclosure

In a solar cell using a compound semiconductor, CuInSe₂ (hereinafter, referred to as “CIS”) as an group compound semiconductor is highlighted as an absorber layer material. The CIS has several advantages of having 1.02 eV of direct transition type energy band gap and high photoconversion efficiency and long-term stability due to having much a higher light absorption coefficient than silicon. The compound thin film solar cell well coincides with a conception of a thin film solar cell desiring to reduce consumption of raw materials, and exhibits higher efficiency than a thin film solar cell using a silicon material. Studies have been made in the related art on such thin film solar cell using the CIS semiconductor by way of co-evaporation, sputtering, synthesis of nano powders, or the like.

Cu(In,Ga)Se₂ (hereinafter, referred to as “GIGS”) is a compound semiconductor containing four different raw materials, such as Cu, In, Ga and Se. Fabrication methods of CIGS thin film include an evaporation method, a sputtering+selenization method, an electrodeposition method and the like. However, those methods have not yet reached at the stage of mass production due to complexity of a production process and non-uniformity of composition within the prepared material. Studies on nano materials for overcome the non-uniformity of composition and improving efficiency are on the rise.

Studies on synthesis method of nanowire and nanotube using vapor synthesis, solution-liquid-solid (SLS) method, and template have been reported.

According to the report of H. Peng et al., single crystal In₂Se₃ nanowire and CuInSe₂ nanowire with high crystalinities have been synthesized using metal nano particles as a catalyst through the vapor synthesis. [1] According to this report, the synthesis of the highly crystalline CIS nanowire has been enabled, but an additional process of removing the catalyst for device application is necessary to be carried out.

According to A. J. Wooten et al., raw materials of Cu, In and Se have been dissolved in a polar solution to grow nanowires using golden nanoparticles as a catalyst through the SLS method. [2] However, this method also requires an addition process of removing the catalyst particles. Further, the synthesized nanowires have a disadvantage of the non-uniform composition.

The synthesis of the nanowire and the nanotube using the template is a method of growing a CIS nanotube on a surface of ZnO nanorod within a solution using exchange of negative ion and positive ion. [3] However, the nanotube synthesized by this method has poor crystallinity.

In recent time, studies on nano materials, which have a well-defined nano border, which provide a conduction path way of electrons, which can control band gap energy according to their size, and which exhibit high device applicability due to light absorption rate increasing by virtue of a wide special surface area, are necessary to come to the fore.

Meanwhile, although the synthesis of the CIS nanowire and the nanotube is enabled, any successful synthesis of the crystalline CIGS nanowires have not been reported until recent time, with merely reporting that the CIGS nanowire synthesis using membrane is allowed. This method uses an anodic alumina membrane (AAM). The CIGS nanowire synthesized by this method is an amorphous CIGS nanowire without crystallinity. [4]

Therefore, the present disclosure proposes a method of fabricating high-quality single crystal GIGS nanowire with substantially uniform composition and high crystallinity using thermal-CVD, without use of a catalyst.
[1] H. Peng, D. T. Schoen, S. Meister, X. F. Zhang, and Y. Cui, Synthesis and phase transformation of In2Se3 and CuInSe2 nanowires, J. Am. Chem. Soc. 129 (2007), 34-35.
[2] A. J. Wooten, D. J. Werder, D. J. Williams, J. L. Casson, and J. A. Hollingsworth, Solution-liquid-solid growth of ternary Cu—In—Se semiconductor nanowires from multiple and single source precursors, J. Am. Chem. Soc. 131 (2009) 16177-16188.
[3] J. Xu, C. Y. Luan, Y. B. Tang, X. Chen, J. A. Zapien, W. J. Zhang, H. L. Kwong, X. M. Meng, S. T. Lee, and C. S. Lee, low-temperature synthesis of CuInSe2 nanotube array on conducting glass substrates for solar cell application, ACS Nano 4(2010) 6064.
[4] R. Inguanta, P. Livreri, S. Piazza, and C. Sunseri, Fabrication and photoelectrochemical behavior of ordered CIGS nanowire arrays for application in solar cells, Electrochemical and Solid-State Letters, 13 (2010), K22-K25.

### SUMMARY OF THE DISCLOSURE

Therefore, an aspect of the detailed description is to provide Cu(In,Ga)Se₂ nanorod or nanowire, as a direct transition type semiconductor material, which has substantially uniform composition, high crystalinity and high absorption rate, and prepared by using a thermal-chemical vapor deposition (thermal-CVD) without use is of a catalyst. The nanorod or nanowire can be utilized to solar cells, image sensors, photo detectors and the like.

To achieve these and other advantages and in accordance with the purpose of this specification, as embodied and broadly described herein, there is provided a method of fabricating nanorod or nanowire, the method including a deposition preparation step of placing a substrate and a raw material comprising copper, indium, gallium and selenium; and a deposition step of growing CIGS nanorod or nanowire, which contains a compound expressed by the following Chemical Formula 1, on the substrate by maintaining an internal temperature of a reactor, in which carrier gas flows at a substantially constant flow rate, at a temperature in the range of 850 to 1000° C.

Cu(Inₐ,Ga_{b})Se₂ [Chemical Formula 1]

where the a is a real number in the range of 0<a<1, the b is a real number in the range of 0<b<1, and a+b=1.

The fabrication method may further include a cleaning step between the reaction preparation step and the deposition step. The cleaning step may include a stage of removing impurities within the reactor by introducing the carrier gas into the reactor after changing the reactor into a vacuum state.

The raw material may include a first material containing copper, indium, gallium and selenium sources, and a second material containing copper source. A ratio between a first distance from the substrate to the first material and a second distance from the substrate to the second material may be 1:1 to 3.

The copper source may include one selected from the group consisting of copper, iodized copper and a combination thereof.

The substrate, the first material and the second material may be substantially located on a straight line horizontal to a plane of a plate within the reactor.

Assuming that the sum of indium and gallium as a reference is 1, the raw material may contain 0.8 to 1.2 parts per weight of copper, and 2 to 2.3 parts per weight of selenium.

During the deposition step, a temperature difference between the substrate and the first material may be in the range of 60 to 90° C.

The deposition step may further include a stage of increasing the internal temperature of the reactor, and the temperature increase may be carried out at 10 to 30° C./min.

The deposition step may be carried out for 1 to 7 hours.

The carrier gas may include one selected from the group consisting of hydrogen, nitrogen, argon, inert gas and combinations thereof.

The carrier gas may be supplied by 5 to 200 sccm.

The Cu(In,Ga)Se₂ nanorod or nanowire may be a single crystal which is epitaxially grown on the substrate.

A material in accordance with another exemplary embodiment includes GIGS nanorod or nanowire expressed by the chemical formula 1.

The GIGS nanorod or nanowire may be a single crystal and may include a tetragonal structure.

The long-axis direction of the GIGS nanorod or nanowire may be [110].

The nanorod may be 1 to 100 μm in length, and 500 nm to 1 μm in diameter, and the nanowire may be 10 nm to 500 nm in diameter and 1 to 100 μm in length.

A solar cell in accordance with another exemplary embodiment include the material of GIGS nanorod or GIGS nanowire.

A nanosensor in accordance with another exemplary embodiment include the material of GIGS nanorod or GIGS nanowire.

Since GIGS as a compound semiconductor containing Cu, In, Ga and Se comprises four different chemical elements with different properties, it is very difficult to fabricate a large size CIGS with substantially uniform composition. Therefore, the inventors of the present disclosure have accomplished the present invention by succeeding a fabrication of single crystal GIGS nanorod and nanowire with substantially uniform composition and excellent crystallinity using a thermal-chemical vapor deposition (thermal-CVD). Hereinafter, a configuration of the present disclosure will be described in detail.

A method of fabricating nanorod or nanowire in accordance with one exemplary embodiment comprises a deposition preparation step and a deposition step, so as to provide CIGS nanorod or nanowire, which has grown on a substrate and contains a compound expressed by the following chemical formula 1.

Cu(Inₐ,Ga_{b})Se₂ [Chemical Formula 1]

where the a is a real number in the range of 0<a<1, the b is a real number in the range of 0<b<1, and a+b=1. The a and the b may meet such conditions that the a is a real number in the range of 0.2<a<0.6, the b is a real number in the range of 0.4<a<0.8 and a+b=1.

The deposition preparation step may include a stage of placing raw materials comprising copper, indium, gallium and selenium, and a substrate within is a reactor. The nanorod or nanowire can be grown without use of a catalyst for the growth of the nanorod or nanowire substantially. Therefore, a step of removing the catalyst after completion of the fabrication of the nanorod or nanowire may not be required. This is one of excellent characteristics of the present disclosure, which is distinguishable over the conventional methods.

The raw materials comprise a first material containing copper, indium, gallium and selenium sources, and a second material containing copper source. The substrate, the first material and the second material may be substantially located on a straight line horizontal to a plane of a plate within the reactor.

Assuming that the sum of indium and gallium as a reference is 1, the raw material may contain 0.8 to 1.2 parts per weight of copper, and 2 to 2.3 parts per weight of selenium. When the raw materials are used in the above range of the content, the GIGS nanorod or nanowire may be properly formed.

A ratio between a first distance from the substrate to the first material and a second distance from the substrate to the second material may be 1:1 to 3. When the deposition of the nanorod or nanowire is carried out with maintaining the above distances, the nanorod or nanowire with the aforementioned composition may be synthesized although those elements have different deposition ratios from each other.

The second material may include one selected from a group consisting of copper, iodized copper and combinations thereof. When the second material is used separately, the content of copper contained in the nanorod or nanowire may increase more than the content of copper contained in the nanorod or nanowire when using only the first material. If the first material includes copper selenide (CuSe) as the copper source, the second material can compensate for the characteristic of CuSe with a high melting point, and the GIGS nanorod or nanowire may have a proper composition.

The fabrication method may further comprise a cleaning step between the reaction preparation step and the deposition step. The cleaning step may include a stage of removing impurities within the reactor by introducing the carrier gas into the reactor after changing the reactor into a vacuum state. Through performing the cleaning step, the nanorod or nanowire which is not defective and is highly pure may be acquired.

The deposition step may include a stage of growing GIGS nanorod or nanowire on the substrate, which contains a compound expressed by the chemical formula 1 by way of maintaining the inside of the reactor at a temperature in the range of 850 to 1000° C. in which carrier gas flows at a substantially constant flow rate.

When the internal temperature of the reactor exceeds the range of 850 to 1000° C. during the deposition step, the synthesis of the CIGS nanorod or nanowire may be failed in or the desired composition of a nanorod or nanowire may be difficult to be achieved.

The deposition step may comprise a stage of rising an internal temperature of the reactor, and the internal temperature of the reactor may be risen in the range of 10 to 30° C./min, or 10 to 20° C./min.

The deposition step may be carried out for 1 to 7 hours with maintaining the internal temperature of the reactor. When the deposition step is executed for less than 1 hour, the synthesis of the nanorod or nanowire may be insufficient. When the deposition step is executed over 7 hours, the deposition for a desired nanorod or nanowire may be failed and only a kind of thin film may be achieved.

The carrier gas may comprise one selected from the group consisting of hydrogen, nitrogen, inert gas and combinations thereof. The inert gas may be one selected from the group consisting of purified argon and nitrogen thereof. Also, the carrier gas in the cleaning step and the carrier gas in the deposition step may be the same or different from each other.

The carrier gas may be supplied by 5 to 200 sccm, or 5 to 100 sccm. When the flow rate of the carrier gas is within the above range, the carrier gas may serve to transfer the gas phases of the raw material, which are volatilized during the deposition step, toward the substrate with an appropriate speed.

During the deposition procedure, a temperature difference between the substrate and the first material may be in the range of 60 to 90° C. When the temperature of the raw material containing the first material higher than the temperature of the substrate is maintained with the above temperature difference, the nanorod or nanowire may be grown more efficiently.

The Cu(In,Ga)Se₂ nanorod or nanowire may have a single crystalline structure which is epitaxially grown on the substrate. The substrate may be any one on which the nanorod or nanowire can be grown, and there may not be any specified limit on a material or shape of the substrate.

The nanorod or nanowire synthesized by the above method may be a single crystalline material with excellent crystallinity and rarely having a plane defect or a line defect, and also be a nanorod or nanowire having a high distribution property due to substantially uniform distribution of the four elements included within the nanorod or nanowire. The nanorod or nanowire may include a tetragonal structure or be formed into the structure. Also, the long-axis direction thereof may be [110]. The nanorod or nanowire may be a semiconductor material having about 1.12 eV of band gap. In addition, since the nanorod or nanowire has a high light absorption coefficient of 10⁵ cm⁻¹, high photoconversion efficiency and high device stability may be provided to a solar cell when the nanorod or nanowire is applied as a photoelectrode material thereof.

The nanorod may be 1 to 100 am in length, and 500 nm to 1 μm in diameter. The nanowire may be 10 nm to 500 nm in diameter and 1 to 100 μm in length.

The four-element compound nanowire (or nanorod) containing copper, indium, gallium and selenium is very difficult to be grown since the elements have different vaporization degrees each other with high environmental sensitivities. However, the present disclosure provides a synthesis method of the four-element compound nanowire (or nanorod) using a thermal-chemical vapor deposition (thermal-CVD). A CIGS nanowire or nanorod according to the present disclosure may have an advantage in that it is a single crystal with high purity and high quality. Also, the present disclosure may have an advantage of fabricating a high-quality nanowire, which has excellent light absorption coefficient and high purity without impurities mixed and has no crystal defect. In addition, the present disclosure may provide a nano material with a high device applicability due to a length, a thickness and the like of the nanorod or nanowire being adjustable by changing conditions for deposition. And also a composition rate of the nanowire or nanorod is adjustable.

A material in accordance with another exemplary embodiment of the present disclosure includes CIGS nanorod or nanowire expressed by the following chemical formula 1.

Cu(Inₐ,Ga_{b})Se₂ [Chemical Formula 1]

The chemical formula 1 and the nanorod or nanowire is understood by the aforementioned description of the fabrication method of the nanorod or nanowire, so such detailed description thereof will be omitted.

The CIGS nanorod or nanowire may consist of a single crystalline structure. Also, the CIGS nanorod or nanowire may consist of a tetragonal structure. The CIGS nanorod or nanowire may have the long-axis direction of [110]. The CIGS nanorod or nanowire may be located on the substrate, and a boundary between the substrate and the nanorod or nanowire may exhibit a diffraction pattern having both the diffraction pattern of the substrate and the diffraction pattern of the nanorod or nanowire. This means that the CIGS nanorod or nanowire may rarely have a plane defect or a line defect during growth on the substrate and have a characteristic as a single crystal with substantially uniform composition and high quality. In this case, a CIGS nanorod or nanowire with high quality can be provided.

The nanorod may be 1 to 100 μm in length, and 500 nm to 1 μm in diameter. The nanowire may be 10 nm to 500 nm in diameter and 1 to 100 μm in length.

The present disclosure may provide a material capable of being fabricated even on a mass scale such that CIGS compound semiconductor as a multi-element compound containing four elements, which has been actually impossible to be fabricated in uniform composition during formation in a large size, can be fabricated into the form of nanorod or nanowire with substantially uniform composition and high crystallinity. The material may have a light absorption coefficient of 10⁵ cm⁻¹, which is higher than that of CuInSe₂ (CIS) material as the conventional group compound semiconductor. This indicates that the material is cable of obtaining much higher photoconversion efficiency than a general silicon material.

A solar cell in accordance with another exemplary embodiment of the present disclosure includes the material. Specifically, the material may be advantageously applied to an absorber layer of the solar material. The nano material according to the present disclosure is the CIGS compound semiconductor which has the substantially uniform composition and the high crystallinity, so as to enhance the performance of the solar cell.

A nanosensor in accordance with another exemplary embodiment of the present disclosure includes the material. The material may include nanorod or nanowire formed of a semiconductor material with high uniformity and a high band gap, which may allow for providing a nanosensor with a high performance.

The CIGS was difficult to be synthesized as a nanorod or nanowire shape, comparing with the synthesis of GIGS as a thin film or nanoparticle shape. This causes a difficulty of synthesis for the CIGS nanorod or nanowire to have a certain aspect ratio more than a predetermined level, to have a single crystalline structure, and to have a substantially uniform composition ratio of four elements in a thickness or lengthwise directions, without the use of a catalyst.

On the contrary, the GIGS thin film or nanoparticle is relatively easy to be synthesized but each grain or nanoparticle included in a piece or thin film has a different growing direction and a different composition ratio, which may result in lowering of a general uniformity of a device. Therefore, formation of the GIGS thin film or nanoparticle with a uniform characteristic is also difficult.

However, the present disclosure has synthesized a nanorod or nanowire with substantially uniform composition in lengthwise and thickness directions by applying a thermal-chemical vapor deposition. The present disclosure also provide a method of synthesis a four-element compound semiconductor, such as CIGS, even with substantially uniform composition and high crystallinity.

A method of fabricating a nanorod or nanowire can provide a method of synthesizing a GIGS in a form of nanorod or nanowire by a thermal-chemical vapor deposition. The synthesized nanorod or nanowire may be a four-element compound and also a single crystal with high purity and high quality, so as to have a great aspect ratio and a high light absorption coefficient. Also, the nanorod or nanowire with the high purity and high quality can be provided due to rarely having mixed impurities and crystal defect. The nanorod or nanowire may be utilized for a solar cell, an image sensor, a semiconductor device, a photo detector and the like.

Further scope of applicability of the present application will become more apparent from the detailed description given hereinafter. However, it should be understood that the detailed description and specific examples, while indicating preferred embodiments of the disclosure, are given by way of illustration only, since various changes and modifications within the spirit and scope of the disclosure will become apparent to those skilled in the art from the detailed description.

### BRIEF DESCRIPTION OF THE DRAWINGS

The accompanying drawings, which are included to provide a further understanding of the disclosure and are incorporated in and constitute a part of this specification, illustrate exemplary embodiments and together with the is description serve to explain the principles of the disclosure.

FIG. 1 is a conceptual view of a reactor used in the example of the present disclosure.

FIG. 2 illustrates scanning electron microscopic (SEM) photos of a CIGS nanowire synthesized in accordance with example (1) of the present disclosure. A photo at a left-hand side is a SEM photo of a nanorod and nanowire synthesized on a substrate. The top photo among the small photos at a right side is an enlarged photo of the nanowire, a middle photo is an enlarged photo of an end of the nanowire represented with a solid line square of upper side, and the bottom photo is an enlarged photo of the other end where a substrate and the nanowire, represented with a solid line square of down side, come in contact with each other.

FIG. 3 is a transmission electron microscopic (TEM) photo of a nanowire fabricated in accordance with example (1) to analyze a distribution of composition as to a grown nanowire.

FIG. 4 is a STEM/EDS result for checking a distribution of composition at each position of a section in a lengthwise direction, indicated with A to E in FIG. 3.

FIG. 5 is a STEM/EDS result of the sample shown in FIG. 3 for checking a composition distribution of a section perpendicular to the lengthwise direction.

FIG. 6 shows high-resolution TEM photos for checking a growth relationship between the synthesized GIGS nanowire and the substrate.

FIG. 7 shows selected area electron diffraction (SAED) patterns on the GIGS nanowire synthesized according to example (1), the substrate and an interface between the nanowire and the substrate.

### DETAILED DESCRIPTION OF THE DISCLOSURE

Description will now be given in detail of the examples, with reference to the accompanying drawings. For the sake of brief description with reference to the drawings, the same or equivalent components will be provided with the same reference numbers, and description thereof will not be repeated.

### Examples

### (1) Synthesis of GIGS Nanowire

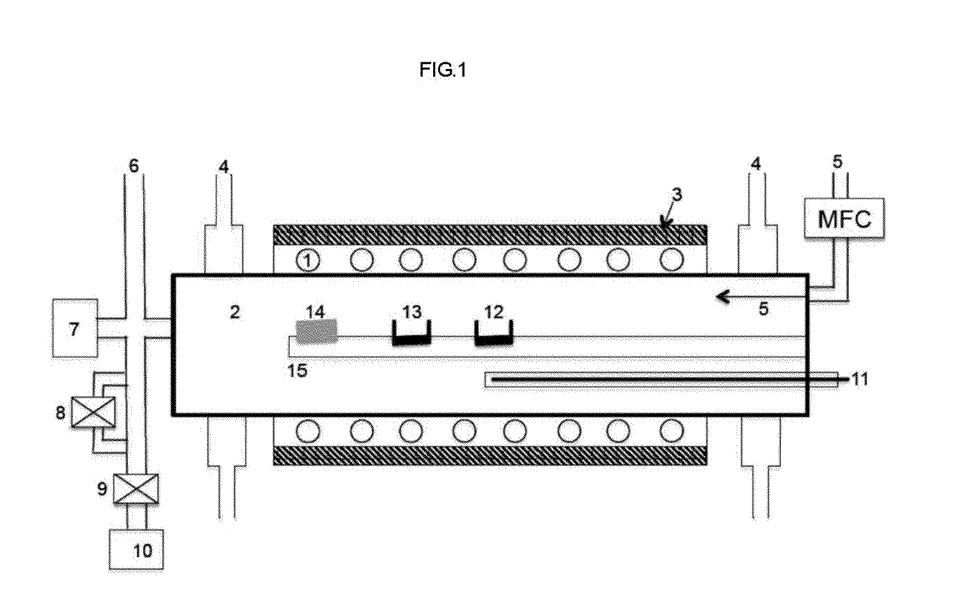

FIG. 1 is a conceptual view of a chemical reactor used for an example of the present disclosure. Hereinafter, a synthesis process of a CIGS nanowire will be described with reference to FIG. 1.

A quartz tube 2 made of quartz was aligned horizontal to a reactor 3. A plate 15 made of quartz was mounted within the quartz tube 3. As shown in FIG. 1, an aluminum crucible 12 (first material), located in a center of the quartz tube 2, was filled with a first material (a raw material as a mixture of 0.1 g of copper selenide powders, 0.1 g of indium selenide powders and 0.1 g of gallium selenide) to be placed on the plate 15, an aluminum crucible 13 (second material) filled with 0.1 g of copper iodide powders (second material) was mounted on a position about 3 cm away from the aluminum crucible 12, and a sapphire substrate 14 was placed on a position about 7 cm away from the first material 12 (Deposition preparation step).

Prior to carrying out a deposition step, an initial degree of vacuum of the reactor 3 was exhausted down to 10⁻² Torr or below using a rotary pump 10 so as to remove oxygen and impurities which remain in the reactor 3. When reaching a preset degree of vacuum, a mixture gas of hydrogen and nitrogen (carrier gas) was constantly introduced into the reactor 3 by 10 sccm for 20 minutes using a throttle valve 8, thereby removing impurities (Cleaning step).

While the carrier gas as the mixture gas of hydrogen and nitrogen was constantly maintained by 10 sccm, the reactor 3 was heated up to 900° C. at a temperature raising speed of 15° C. per minute. Then, a reaction step was carried out with maintaining the reactor at 900° C. for 3 hours. The temperature difference from the first material to the substrate was adjusted into about 80° C. The copper, the indium, the gallium and the selenium were vaporized from the powders as the raw material and shifted by the mixture gas to be absorbed onto the substrate. Such series of procedures were repeated for a deposition time of 3 hours and accordingly, GIGS nanorod or nanowire was grown on the sapphire substrate (Deposition step).

### (2) Observation of Nanowire Using SEM

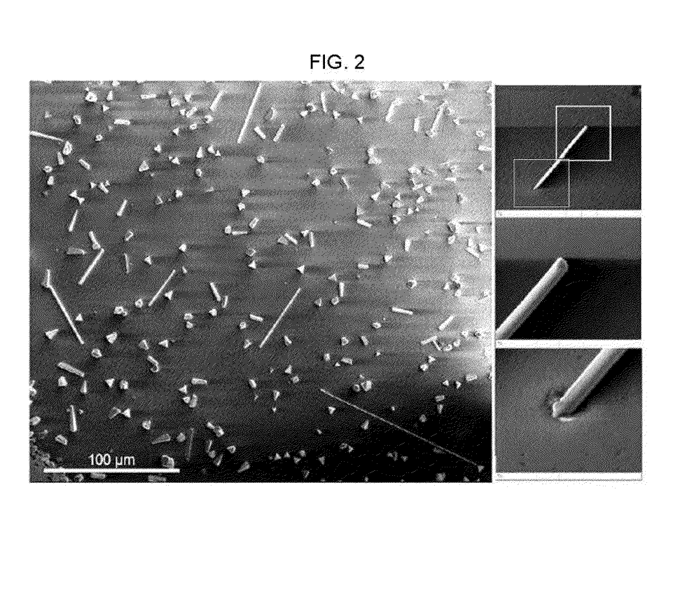

FIG. 2 illustrates scanning electron microscopic (SEM) photos of a GIGS nanowire synthesized in accordance with the example (1). As illustrated in FIG. 2, the synthesized nanowire was observed as having a length in the range of 1 to 100 μm and a thickness in the range of several tens of nm to 1 μm. A photo at a left-hand side is a SEM photo of nanorod and nanowire synthesized on a substrate. The top photo of small photos at a right-hand side is an enlarged photo of the nanowire, a middle photo is an enlarged photo of an end of the nanowire represented with a solid line square of upper side, and the bottom photo is an enlarged photo of the other end where a substrate and the nanowire, represented with a solid line square of down side, come in contact with each other. It was observed, referring to those photos, that the nanowire synthesized according to the example (1) had a clear interface with the substrate and was well grown in a triangular shape.

### (3) Observation of TEM and STEM/EDS for Checking Whether or not Uniform Composition is Exhibited

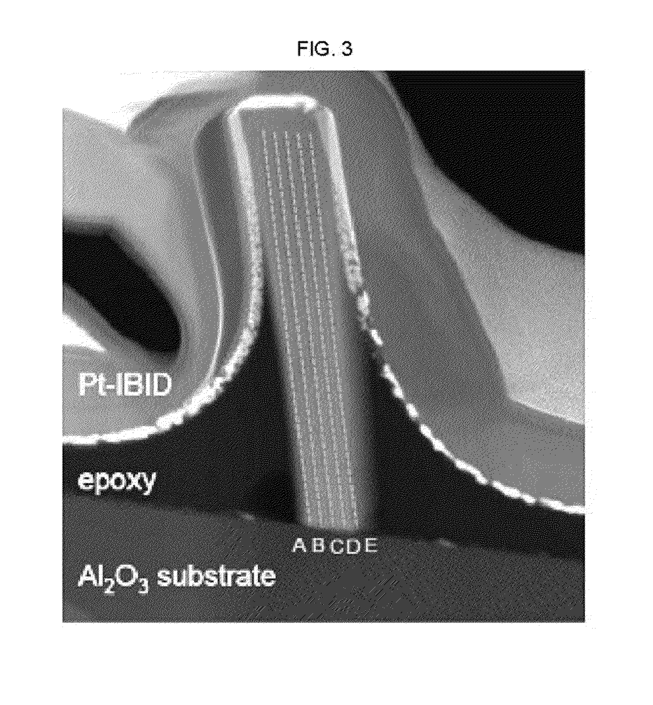

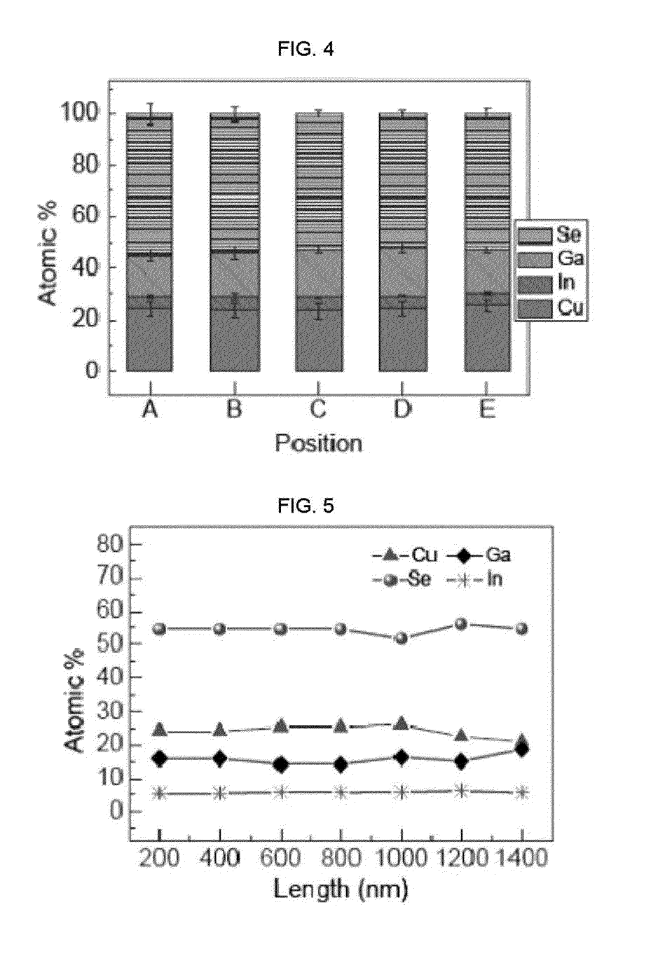

FIG. 3 is a transmission electron microscopic (TEM) photo of a nanowire fabricated in accordance with the example (1) to analyze a distribution of composition for a grown nanowire, FIG. 4 is a STEM/EDS result for checking a distribution of composition at each position of a section in a lengthwise direction, indicated with A to E in FIG. 3, and FIG. 5 is a STEM/EDS result of the sample shown in FIG. 3 for checking a composition distribution of a section perpendicular to the lengthwise direction. Whether or not elements were substantially uniformly distributed in the nanowire was evaluated with reference to FIGS. 3 to 5.

FIG. 3 illustrates photos obtained by preparing a sample (FIG. 3) for observing cross-sections of the substrate and the nanowire using focused ion beam and observing the sample using a scanning transmission electron microscopy (STEM). Analysis results of composition distribution with respect to several areas of the nanowire using an energy dispersive X-ray spectrometry (STEM/EDS) attached onto the TEM were shown in FIGS. 4 and 5.

Referring to FIG. 4, a content ratio of copper:indium:gallium:selenium was 1:0.4:0.6:2 on each section (a section parallel to a lengthwise direction of the nanowire) shown in FIG. 3. Accordingly, it was confirmed that a distribution in a direction perpendicular to a length exhibited substantially uniform composition.

Referring to FIG. 5, since a distribution of the content of each element was is similarly exhibited at a position corresponding to each height of the nanowire based on the substrate, it was understood that each element exhibited a substantially uniform composition without a difference due to the height.

### (4) Observation of High-Resolution TEM Image and SAED for Evaluation of Crystallinity

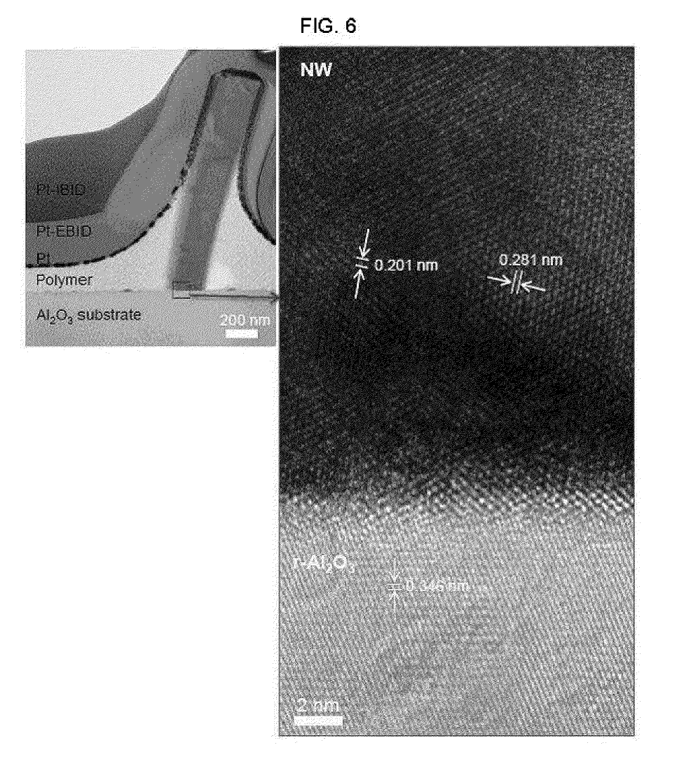

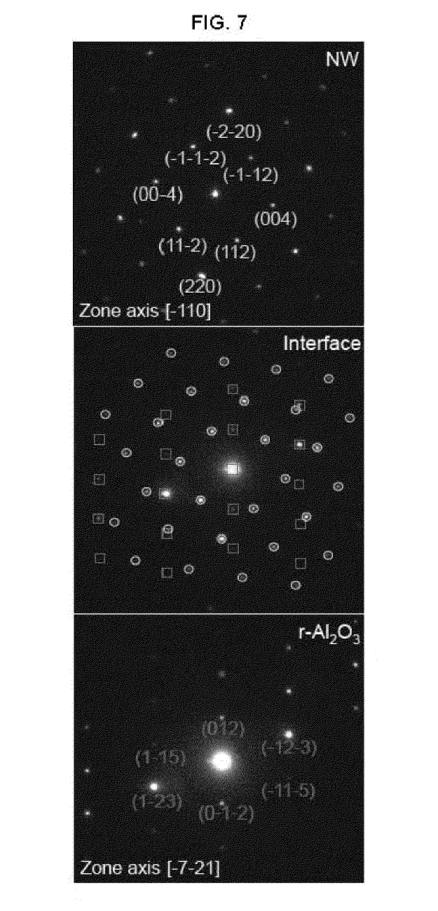

FIG. 6 is a high-resolution TEM photo for checking a growth relationship between the synthesized CIGS nanowire and the substrate, and FIG. 7 is a selected area electron diffraction pattern (SADP) on the CIGS nanowire synthesized according to the example (1), the substrate and an interface between the nanowire and the substrate.

It was confirmed with reference to FIGS. 6 and 7 that crystalline lattices were observed at the interface between the substrate and the nanowire according to the observation result of the high-resolution TEM. It was also observed that a growing direction was [110]. A diffraction pattern of the substrate and that of the nanowire were measured on each area. It was also observed through indexing of the patterns that a growing direction (long-axis direction) of the CIGS nanowire was [110]. Also, the nanowire had high crystallinity and was a high-quality single crystal which rarely had a linear defect and a plane defect. Coexistence of the diffraction patterns of the substrate and the nanowire were observed on the interface between the substrate and the nanowire, and the nanowire was also observed as being epitaxially grown from the substrate.

The foregoing embodiments and advantages are merely exemplary and are not to be construed as limiting the present disclosure. The present teachings can be readily applied to other types of apparatuses. This description is intended to be illustrative, and not to limit the scope of the claims. Many alternatives, modifications, and variations will be apparent to those skilled in the art. The features, structures, methods, and other characteristics of the exemplary embodiments described herein may be combined in various ways to obtain additional and/or alternative exemplary embodiments.

As the present features may be embodied in several forms without departing from the characteristics thereof, it should also be understood that the above-described embodiments are not limited by any of the details of the foregoing description, unless otherwise specified, but rather should be construed broadly within its scope as defined in the appended claims, and therefore all changes and modifications that fall within the metes and bounds of the claims, or equivalents of such metes and bounds are therefore intended to be embraced by the appended claims.

What is claimed is:

1. A method of fabricating nanorod or nanowire, the method comprising:
a deposition preparation step of placing a substrate and raw materials comprising copper, indium, gallium and selenium; and
a deposition step of growing CIGS nanorod or nanowire, which contains a compound expressed by the following Chemical Formula 1, on the substrate by maintaining an internal temperature of a reactor at a temperature in the range of 850 to 1000° C., in which carrier gas flows at a substantially constant flow rate,
Cu(Inₐ,Ga_{b})Se₂ [Chemical Formula 1]
wherein the a is a real number in the range of 0<a<1, the b is a real number in the range of 0<b<1, and a+b=1.

2. The method of claim 1, further comprising a cleaning step between the deposition preparation step and the deposition step,
wherein the cleaning step comprises a stage of removing impurities within the reactor by introducing the carrier gas into the reactor after changing the reactor into a vacuum state.

3. The method of claim 1, wherein the raw material comprises a first material containing copper, indium, gallium and selenium sources, and a second material containing copper source, and
wherein a ratio between a first distance from the substrate to the first material and a second distance from the substrate to the second material is 1:1 to 3.

4. The method of claim 3, wherein the copper source comprises one selected from the group consisting of copper, iodized copper and a combination thereof.

5. The method of claim 3, wherein the substrate, the first material and the second material are substantially located along a straight line horizontal to a plane of a plate within the reactor.

6. The method of claim 3, wherein assuming that the sum of indium and gallium as a reference is 1, the raw material contains 0.8 to 1.2 parts per weight of copper, and 2 to 2.3 parts per selenium.

7. The method of claim 3, wherein during the deposition step, a temperature difference between the substrate and the first material is in the range of 60 to 90° C.

8. The method of claim 1, wherein the deposition step further comprises a stage of increasing the internal temperature of the reactor, wherein the temperature increase is carried out at 10 to 30° C./min.

9. The method of claim 1, wherein the deposition step is carried out for 1 to 7 hours.

10. The method of claim 1, wherein the carrier gas contains one selected from the group consisting of hydrogen, nitrogen, argon, inert gas and combinations thereof.

11. The method of claim 1, wherein the carrier gas is supplied by 5 to 200 sccm.

12. The method of claim 1, wherein the Cu(In,Ga)Se₂ nanorod or nanowire has a single crystalline structure which is epitaxially grown on the substrate.

13. A material comprising CIGS nanorod or nanowire expressed by the following Chemical Formula 1,
Cu(Inₐ,Ga_{b})Se₂ [Chemical Formula 1]
wherein the a is a real number in the range of 0<a<1, the b is a real number in the range of 0<b<1, and a+b=1.

14. The material of claim 13, wherein the CIGS nanorod or nanowire has a single crystalline and tetragonal structure.

15. The material of claim 13, wherein the long-axis direction of the CIGS nanorod or nanowire is [110].

16. The material of claim 13, wherein the CIGS nanorod or nanowire is located on a substrate, and an interface between the substrate and the nanorod or nanowire exhibits both a diffraction pattern of the substrate and a diffraction pattern of the nanorod or nanowire.

17. The material of claim 13, wherein the nanorod is 1 to 100 μm in length, and 500 nm to 1 μm in diameter, and the nanowire is 10 nm to 500 nm in diameter and 1 to 100 μm in length.

18. A solar cell having the material according to claim 13.

19. A nanosensor having the material according to claim 13.
